(19) United States
(12) Patent Application Publication
(10) Pub. No.: US 2015/0021767 A1
(43) Pub. Date: Jan. 22, 2015

(54) SEMICONDUCTOR DEVICE WITH PLATED CONDUCTIVE PILLAR COUPLING

(71) Applicants: Doo Hyun Park, Gyeonggi-do (KR); Seong Min Seo, Songpa-gu (KR); Wang Gu Lee, Gyeonggi-do (KR); Jong Sik Paek, Incheon (KR); Won Chul Do, Gyeonggi-do (KR)

(72) Inventors: Doo Hyun Park, Gyeonggi-do (KR); Seong Min Seo, Songpa-gu (KR); Wang Gu Lee, Gyeonggi-do (KR); Jong Sik Paek, Incheon (KR); Won Chul Do, Gyeonggi-do (KR)

(21) Appl. No.: 14/063,829

(22) Filed: Oct. 25, 2013

(30) Foreign Application Priority Data
Jul. 16, 2013 (KR) 10-2013-0083819

(51) Int. Cl. H01L 23/00

(52) U.S. Cl. CPC H01L 24/13; H01L 24/81; H01L 24/05
USPC 257/738; 257/737; 438/126

(57) ABSTRACT

A semiconductor device with plated conductive pillar coupling is disclosed and may include a semiconductor die comprising a conductive pillar formed on a bond pad on the die, a substrate comprising an insulating layer with conductive patterns formed on a first surface of the substrate and a second surface opposite to the first surface, and a plating layer electrically coupling the conductive pillar and the bond pad on the first surface of the die to the conductive pattern on the first surface of the substrate. The conductive pillar, the conductive patterns, and the plating layer may comprise copper. The plating layer may fill a void between the copper pillar and the conductive pattern on the first surface of the substrate. The substrate may comprise a rigid circuit board, a flexible circuit board, a ceramic substrate, a semiconductor die, or semiconductor wafer.

### CROSS REFERECE TO RELATED APPLCIATIONS

The present application makes reference to, claims priority to, and claims the benefit of Korean Patent Application No. 10-2013-0083819, filed on Jul. 16, 2013, the contents of which are hereby incorporated herein by reference, in their entirety.

### FIELD OF THE INVENTION

Certain embodiments of the invention relate to semiconductor chip packaging. More specifically, certain embodiments of the invention relate to a semiconductor device with plated conductive pillar coupling.

### BACKGROUND

In general, a semiconductor device includes a circuit board, a semiconductor die electrically connected to the circuit board, an encapsulant encapsulating the semiconductor die, and solder balls connected to the circuit board.

Here, the semiconductor die is electrically connected to the circuit board by reflow using solder bumps or thermal compression bonding.

Heterogeneous materials (for example, solder) may be disposed between the semiconductor die and the circuit board, so that electromigration may frequently occur to a connected interface, thereby lowering connection reliability of the connected interface.

In addition, since the conventional semiconductor device manufacturing method necessarily involves a thermal process, warpage due to a difference in the thermal expansion coefficients may occur, making it difficult to adopt a manufacturing method based on a large-sized panel.

Further limitations and disadvantages of conventional and traditional approaches will become apparent to one of skill in the art, through comparison of such systems with the present invention as set forth in the remainder of the present application with reference to the drawings.

### BRIEF SUMMARY

A semiconductor device with plated conductive pillar coupling, substantially as shown in and/or described in connection with at least one of the figures, as set forth more completely in the claims.

Various advantages, aspects and novel features of the present invention, as well as details of an illustrated supporting embodiment thereof, will be more fully understood from the following description and drawings.

### BRIEF DESCRIPTION OF SEVERAL VIEWS OF THE DRAWINGS

FIG. 1A is a cross-sectional view of a semiconductor device according to an example embodiment of the present disclosure.

FIGS. 1B and 1C are enlarged cross-sectional views of portions 1b and 1c of FIG. 1A, in accordance with an example embodiment of the disclosure.

FIGS. 2A through 2E are cross-sectional views illustrating a manufacturing method of a semiconductor device according to an example embodiment of the present disclosure.

FIG. 3A is a bottom view illustrating a panel substrate in the manufacturing method of a semiconductor device according to an example embodiment of the present disclosure.

FIG. 3B is a bottom view illustrating a unit substrate including bus bars, in accordance with an example embodiment of the disclosure.

FIG. 4 is a cross-sectional view of a semiconductor device according to another example embodiment of the present disclosure.

FIG. 5 is a plan view illustrating a state in which a plurality of semiconductor dies are mounted on a wafer in a manufacturing method of a semiconductor device according to an example embodiment of the present disclosure.

### DETAILED DESCRIPTION

Certain aspects of the disclosure may be found in a semiconductor device with plated conductive pillar coupling. Example aspects of the disclosure may comprise a semiconductor die comprising a conductive pillar formed on a bond pad on the semiconductor die, a substrate comprising an insulating layer with conductive patterns formed on a first surface and a second surface opposite to the first surface of the substrate, and a plating layer electrically coupling the conductive pillar and the bond pad on the first surface of the semiconductor die to the conductive pattern on the first surface of the substrate. The conductive pillar, the conductive patterns, and the plating layer may comprise copper, for example. The plating layer may fill a void between the copper pillar and the conductive pattern on the first surface of the substrate. The substrate may comprise a rigid circuit board, a flexible circuit board, a ceramic substrate, a semiconductor die, or semiconductor wafer. The plating layer may form a cylindrical shape around the conductive pillar and the conductive pattern on the first surface of the substrate. The substrate may comprise conductive vias that electrically couple the conductive patterns on the first and second surfaces of the substrate. A solder ball may be formed on the conductive patterns on the second surface of the substrate. An encapsulating material may encapsulate the semiconductor die and the first surface of the substrate. An underfill material may be formed between the first surface of the semiconductor die and the first surface of the substrate. The underfill material may surround the plating layer.

The present invention may be embodied in many different forms and should not be construed as being limited to the example embodiments set forth herein. Rather, these embodiments are provided so that this disclosure will be thorough and complete and will fully convey the concepts of the invention to those skilled in the art, and the present invention will only be defined by the appended claims.

In the drawings, the thickness of layers and regions are exaggerated for clarity. Here, like reference numerals refer to like elements throughout. As used herein, the term “and/or” includes any and all combinations of one or more of the associated listed items.

In addition, the terminology used herein is for the purpose of describing particular embodiments only and is not intended to be limiting of the invention. As used herein, the singular forms are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present invention.

In addition, the term “substrate” used herein includes, for example and without limitation, a rigid circuit board, a flexible circuit board, a ceramic substrate, a semiconductor die or wafer.

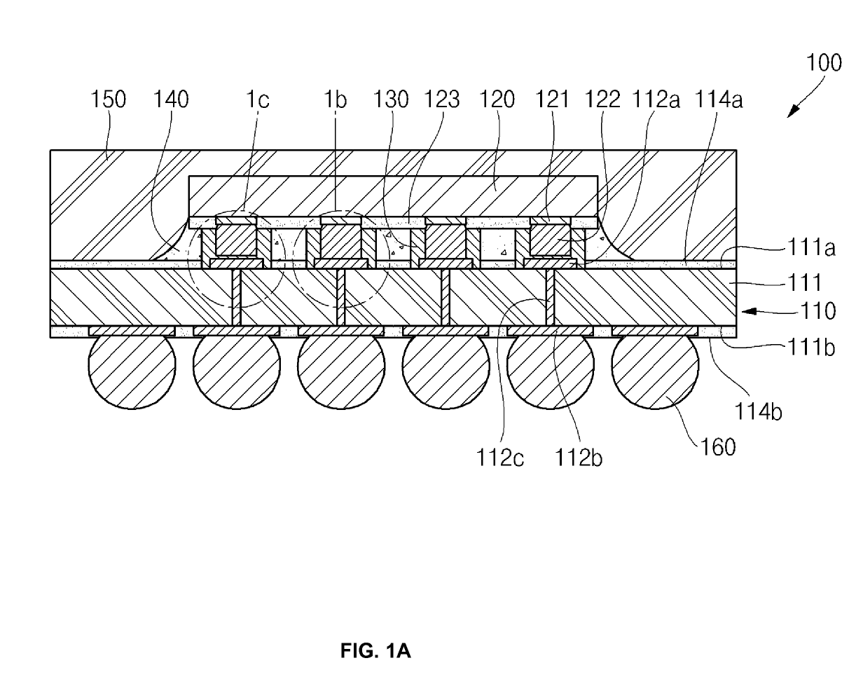

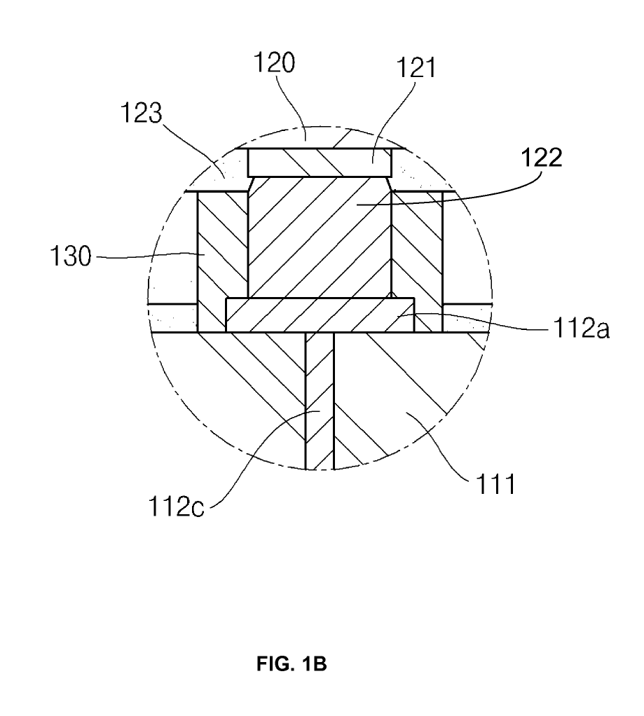

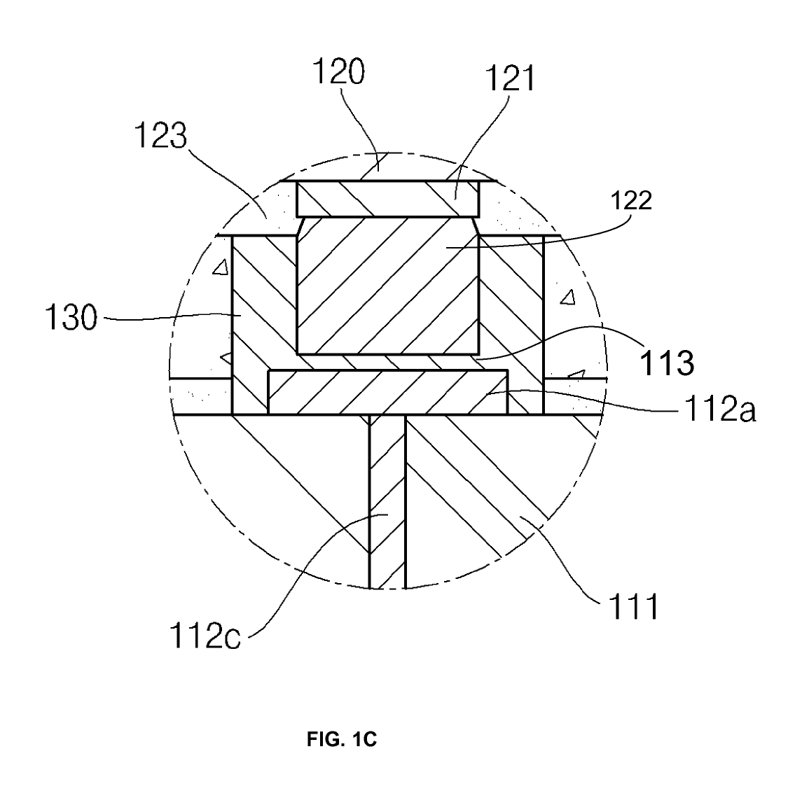

FIG. 1A is a cross-sectional view of a semiconductor device according to an example embodiment of the present invention and FIGS. 1B and 10 are enlarged cross-sectional views of portions 1b and 1c of FIG. 1A.

An example embodiment of the present disclosure provides a semiconductor device and a manufacturing method thereof which can eliminate an electromigration phenomenon by electrically connecting a semiconductor die and a circuit board or a semiconductor die and another semiconductor die using a plating method, and can improve connection reliability of a connected interface.

An example embodiment of the present disclosure also provides a semiconductor device and a manufacturing method thereof, which can suppress warpage by electrically connecting a semiconductor die and a circuit board or a semiconductor die and another semiconductor die using a plating method not necessitating a thermal process, and can achieve the manufacturing method based on a large-sized panel.

An example embodiment of the present disclosure provides a semiconductor device including a substrate including conductive patterns, a semiconductor die including conductive pillars, the conductive pillars electrically connected to the conductive patterns, and a plating layer electrically connecting the conductive patterns and the conductive pillars.

The plating layer may be integrally formed along a surface of the conductive patterns and a surface of the conductive pillars. The conductive pillars may come into direct contact with the conductive patterns. The conductive pillars may be spaced apart from the conductive patterns, and the plating layer may be interposed in a space formed between the conductive pillars and the conductive patterns. The conductive patterns, the conductive pillars and the plating layer may comprise the same material. The conductive patterns, the conductive pillars and the plating layer may comprise copper (Cu), for example. For example, the conductive patterns, the conductive pillars and the plating layer may comprise only copper.

The plating layer may be shaped of an integrally formed cylinder surrounding the surface of the conductive patterns and the surface of the conductive pillars. The substrate may include an insulating layer having a planar first surface, and a planar second surface opposite to the first surface, the conductive patterns may include first conductive patterns formed on the first surface and second conductive patterns formed on the second surface, and the first conductive patterns and the second conductive patterns may be connected to each other through conductive vias passing through the insulating layer.

The substrate may, for example, be coupled to a second semiconductor die, the second semiconductor die comprising silicon having a planar first surface and a planar second surface opposite to the first surface, the conductive patterns may comprise first conductive patterns formed on the first surface and second conductive patterns formed on the second surface, and the first conductive patterns and the second conductive patterns may be connected to each other through a through silicon via passing through the silicon.

In another example scenario, the present disclosure provides a manufacturing method of a semiconductor device, the manufacturing method including providing a unit substrate comprising a plurality of conductive patterns and a semiconductor die including a plurality of conductive pillars, and placing the unit substrate and the semiconductor die into a plating solution tank to perform electroplating and electrically connecting the conductive patterns of the unit substrate and the conductive pillars of the semiconductor die to each other by a plating layer.

A plurality of unit substrates may be provided on a single panel substrate and conductive patterns of the unit substrates may be connected to conductive bus bars formed at a boundary region between the unit substrates.

The manufacturing method may further include sawing the unit substrates and separating the same from the panel substrate, wherein the bus bars are removed in the sawing.

The panel substrate may comprise an insulating layer having a planar first surface, and a planar second surface opposite to the first surface. The conductive patterns may comprise first conductive patterns formed on the first surface and second conductive patterns formed on the second surface, and the first conductive patterns and the second conductive patterns may be connected to each other through conductive vias passing through the insulating layer.

The panel substrate may be coupled to, for example, a second semiconductor die, where the second semiconductor die comprises silicon having a planar first surface and a planar second surface opposite to the first surface. The conductive patterns may include first conductive patterns formed on the first surface and second conductive patterns formed on the second surface, and the first conductive patterns and the second conductive patterns may be connected to each other through a through silicon via passing through the silicon.

As described above, in an example embodiment of the present disclosure, a semiconductor die and a circuit board or a semiconductor die and another semiconductor die may be electrically connected using a plating method, thereby eliminating an electromigration phenomenon, and connection reliability of a connected interface can be improved accordingly.

In addition, in another embodiment of the present disclosure, a semiconductor die and a circuit board or a semiconductor die and another semiconductor die may be electrically connected using a plating method not necessitating a thermal process, thereby suppressing warpage, and the manufacturing method based on a large-sized panel can be achieved.

As illustrated in FIG. 1A, the semiconductor device 100 according to an example embodiment of the present disclosure comprises a substrate 110, a semiconductor die 120 and a plating layer 130. In addition, the semiconductor device 100 according to an example embodiment of the present invention may further comprise an underfill 140, an encapsulant 150 and solder balls 160.

The substrate 110 includes an insulating layer 111 having a substantially planar first surface 111a and a second surface 111b opposite to the first surface 111a, first conductive patterns 112a formed on the first surface 111a, second conductive patterns 112b formed on the second surface 111b, and conductive vias 112c electrically connecting the first conductive patterns 112a and the second conductive patterns 112b while passing through the insulating layer 111.

Here, the first conductive patterns 112a, the second conductive patterns 112b and the conductive vias 112c may be made of copper (Cu) and equivalents thereof, for example, but aspects of the present invention are not limited thereto.

The first surface 111a of the insulating layer 111 may be protected by a first protection layer 114a and the second surface 111b of the insulating layer 111 may be protected by a second protection layer 114b. The first protection layer 114a protects the first conductive patterns 112a that are not externally exposed and the second protection layer 114b protects the second conductive patterns 112b that are not externally exposed.

The substrate 110 may be one selected from a flexible circuit board, a rigid circuit board, a ceramic substrate and equivalents thereof, but aspects of the present invention are not limited thereto.

The semiconductor die 120 includes a plurality of bond pads 121 formed on its surface facing the substrate 110, and a protection layer 123 may be formed at exterior regions of the bond pads 121. In addition, conductive pillars 122 may be formed on the bond pads 121, and the conductive pillars 122 may be electrically connected to the first conductive patterns 112a of the substrate 110. The conductive pillars 122 may comprise the same material(s) as the first conductive patterns 112a or the second conductive patterns 112b. As an example, the conductive pillars 122 may be made of copper (Cu), a copper (Cu) alloy or equivalents thereof, but aspects of the present invention are not limited thereto.

The plating layer 130 may integrally surround the first conductive patterns 112a and the conductive pillars 122, thereby electrically connecting the first conductive patterns 112a and the conductive pillars 122 to each other. The plating layer 130 may comprise the same materials as the conductive pillars 122 and the first conductive patterns 112a. As an example, the plating layer 130 may be made of copper (Cu), a copper (Cu) alloy or equivalents thereof.

As described above, according to an example embodiment of the present disclosure, since the first conductive patterns 112a, the conductive pillars 122 and the plating layer 130 may comprise the same material, an electromigration phenomenon may not occur at electrically connected regions. That is to say, since the same material, rather than heterogeneous materials, may be interposed between the first conductive patterns 112a and the conductive pillars 122, the electromigration phenomenon may not occur between the first conductive patterns 112a and the conductive pillars 122. In addition, since the electromigration phenomenon is prevented, connection reliability of a connected interface between the substrate 110 and the semiconductor die 120 may be improved.

The underfill 140 may be formed in a gap between the substrate 110 and the semiconductor die 120 and may integrally bond the substrate 110 and the semiconductor die 120. Therefore, a separation phenomenon between the substrate 110 and the semiconductor die 120 due to a difference in the thermal expansion coefficient may be prevented. The underfill 140 may surround the surface of the plating layer 130, thereby preventing the plating layer 130 from being damaged.

The encapsulant 150 may encapsulate the semiconductor die 120 on the substrate 110 and the underfill 140. Therefore, the semiconductor die 120 on the substrate 110 may be protected by the encapsulant 150 from external shock.

The solder balls 160 may be electrically connected to the substrate 110. That is to say, the solder balls 160 may be electrically connected to the second conductive patterns 112b provided in the substrate 110. The solder balls 160 may be utilized to mount the semiconductor device 100 to an external device.

As illustrated in FIG. 1B, the plating layer 130 may be integrally formed along the surfaces of the first conductive patterns 112a and the conductive pillars 122. Here, the conductive pillars 122 may make direct contact with the first conductive patterns 112a, so that the plating layer 130 may not be present at the interface between the conductive pillars 122 and the first conductive patterns 112a. In addition, the plating layer 130 may surround the surfaces (lateral surfaces) of the conductive pillars 122 and the surfaces (lateral surfaces and a portion of the top surface) of the first conductive patterns 112a, thereby providing a substantially cylindrical shape. The plating layer 130 may have a thickness in a range of approximately 1 μm to 500 μm, for example, but aspects of the present invention are not limited thereto.

In addition, as illustrated in FIG. 10, the plating layer 130 may be interposed between the first conductive patterns 112a and the conductive pillars 122. That is to say, the first conductive patterns 112a and the conductive pillars 122 may not make direct contact with each other but may be spaced a predetermined distance apart from each other, forming a void 113. In this case, the void 113 may be filled with the plating layer 130. Due to process variations, the first conductive patterns 112a and the conductive pillars 122 may not make direct contact with each other. For example, in a case where warpage occurs to the semiconductor die 120 or the substrate 110 due to a process error, where lengths of the conductive pillars 122 are not uniform, or where thicknesses of the first conductive patterns 112a are not uniform, the conductive pillars 122 may not come into direct contact with the first conductive patterns 112a. However, since distances between the conductive pillars 122 and the first conductive patterns 112a may be less than approximately 100 μm, the plating layer 130 grown by a plating process may sufficiently electrically connect the conductive pillars 122 and the first conductive patterns 112a. As an example, the plating layer 130 may grow from the surfaces of the first conductive patterns 112a of the substrate 110. If the plating layer 130 grows to a thickness of greater than approximately 100 μm, the plating layer 130 may come into contact with the conductive pillars 122, and current then flows through the conductive pillars 122, so that the plating layer 130 also grows on the surfaces of the conductive pillars 122.

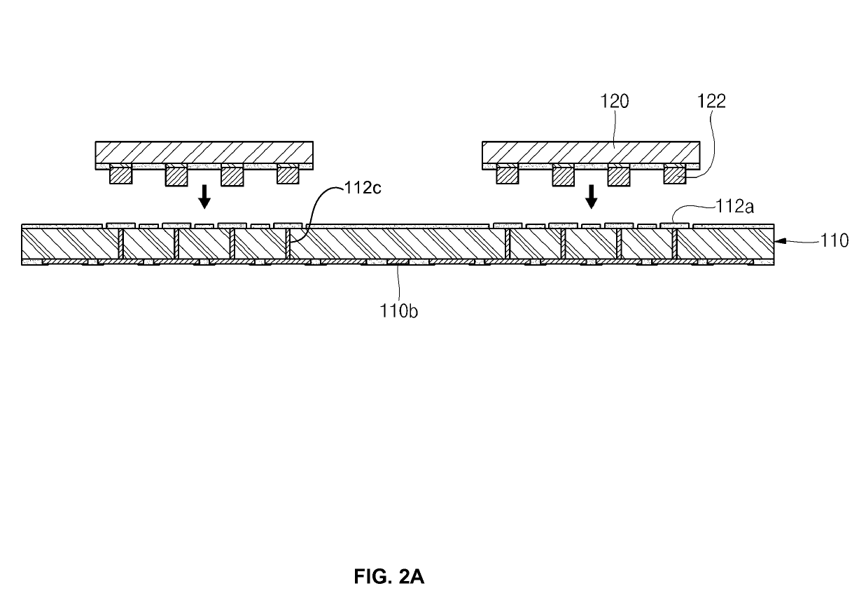

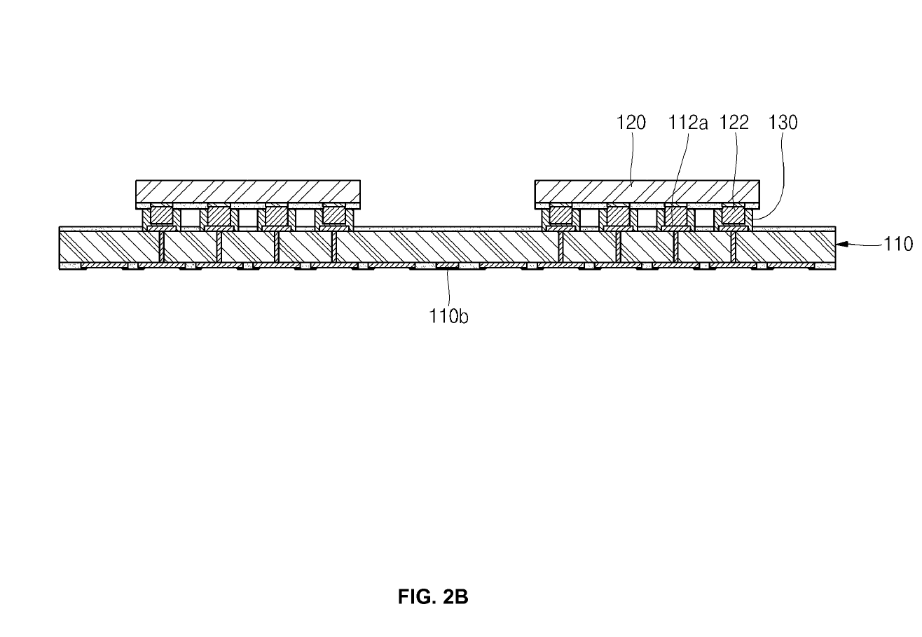

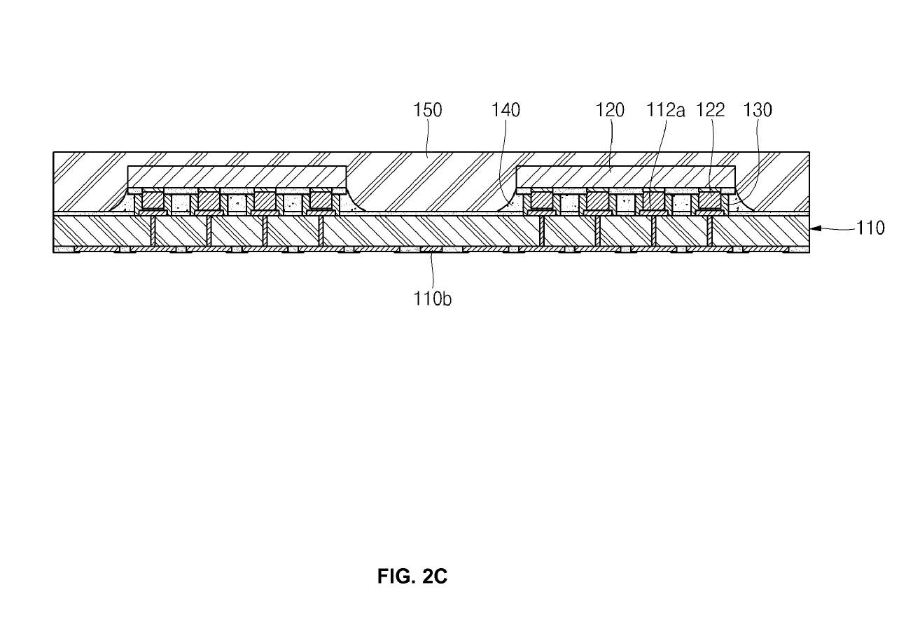

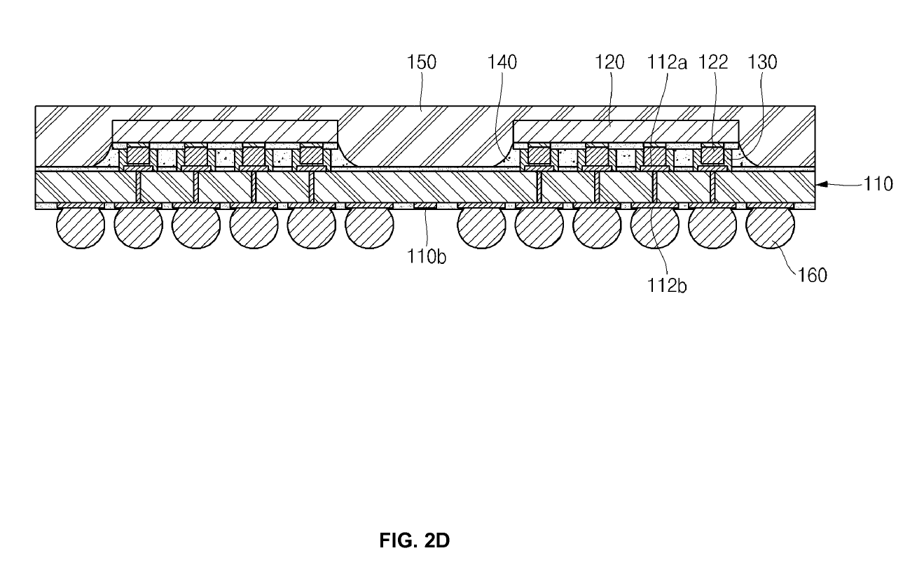

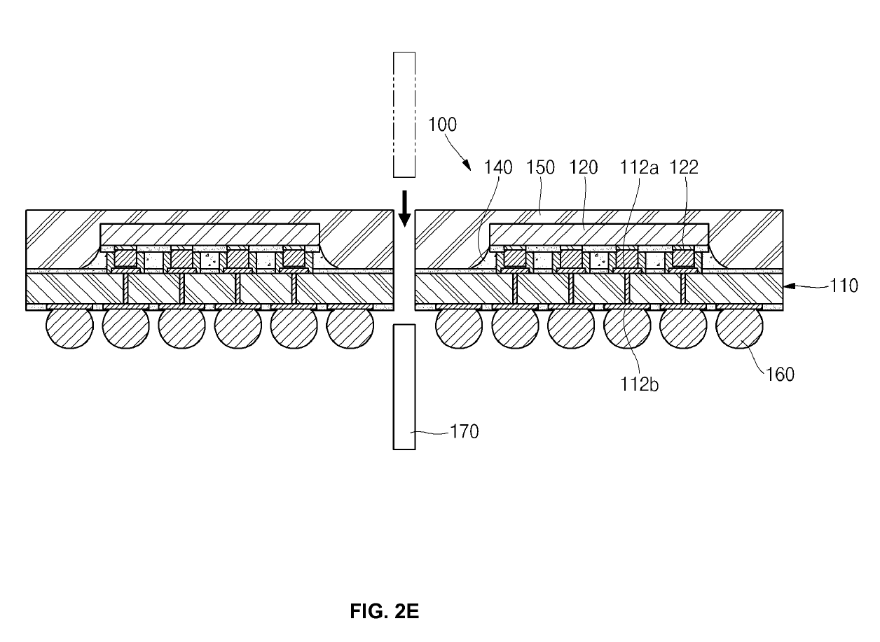

FIGS. 2A through 2E are cross-sectional views illustrating a manufacturing method of a semiconductor device according to an example embodiment of the present disclosure.

The manufacturing method of the semiconductor device 100 according to the present disclosure may comprise providing a unit substrate 110 and a semiconductor die 120, and electrically connecting the unit substrate 110 and the semiconductor die 120 to each other using the plating layer 130 formed by a plating process. In addition, the manufacturing method of the semiconductor device 100 according to the present invention may further include encapsulating, solder ball bonding and sawing.

As illustrated in FIG. 2A, in the providing of the unit substrate 110 and the semiconductor die 120, the unit substrate 110 comprising conductive patterns (first conductive patterns 112a) and the semiconductor die 120 comprising conductive pillars 122 may be provided.

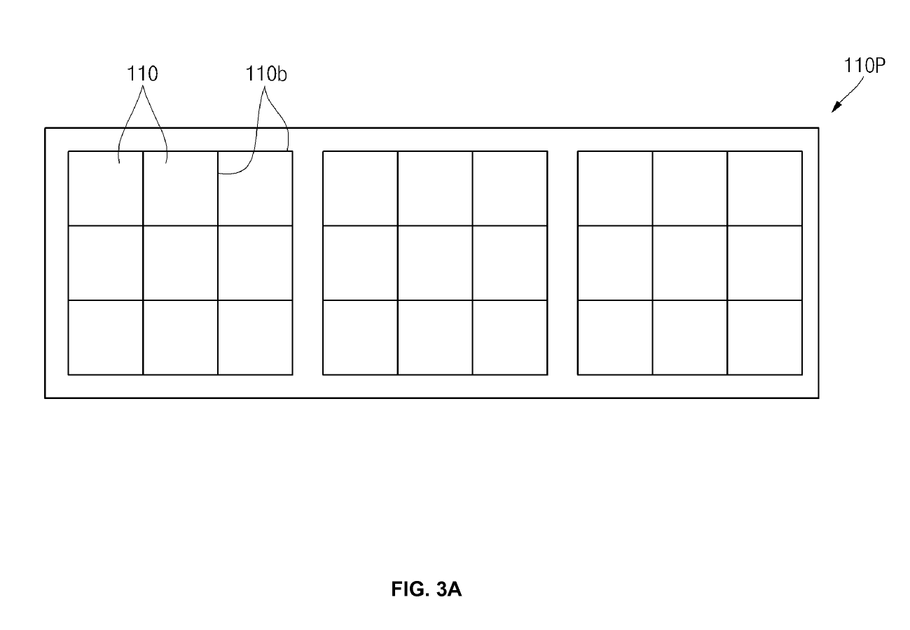

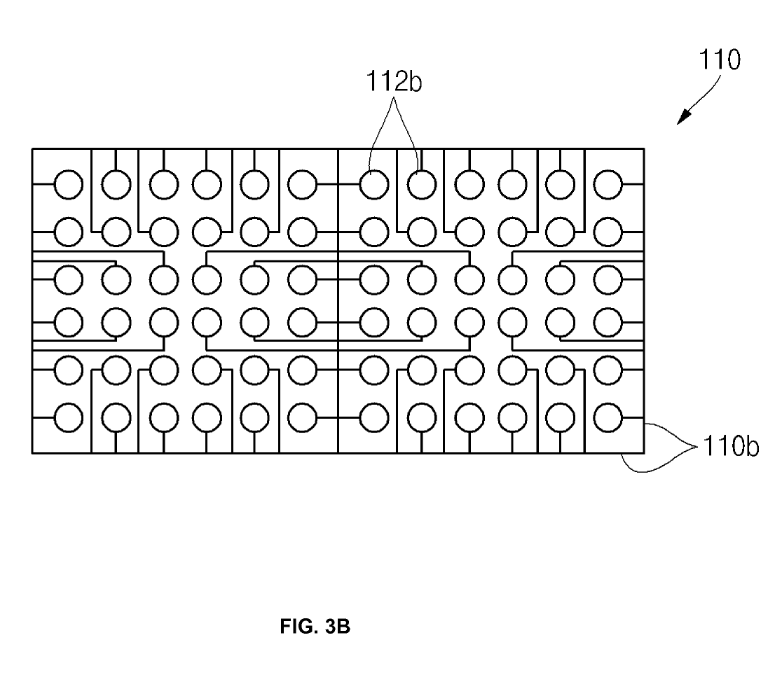

Here, the unit substrate 110 may comprise a plurality of unit substrates formed on a single panel substrate (110p of FIG. 3A), the first conductive patterns 112a may be formed on a first surface 111a of an insulating layer 111, and the second conductive patterns 112b may be formed on a second surface 111b of the insulating layer 111. The first conductive patterns 112a and the second conductive patterns 112b may be connected to each other through conductive vias 112c. In addition, the first conductive patterns 112a and/or the second conductive patterns 112b may be electrically connected to a common bus bar 110b to allow current to flow through during a plating process. In the illustrated embodiment, the bus bar 110b may be formed on the second surface 111b of the insulating layer 111, it may also be formed on the first surface 111a of the insulating layer 111. In addition, the bus bars 110b may be formed at a boundary region between the unit substrates 110 so as to be removed in a later sawing process.

As illustrated in FIG. 2B, in the electrically connecting of the unit substrate 110 and the semiconductor die 120 using the plating layer 130, in instances where the first conductive patterns 112a of the unit substrate 110 and the conductive pillars 122 of the semiconductor die 120 are aligned to make contact with or to be adjacent to each other, the unit substrate 110 and the semiconductor die 120 may be placed into a plating solution tank containing a metal plating solution to perform electroplating, thereby forming the integral plating layer 130 on the surfaces of the first conductive patterns 112a and the conductive pillars 122. For example, a negative potential may be applied to the bus bars 110b and a positive potential may be applied to a copper plate in the plating solution tank, and copper positive ions from the copper plate allow the plating layer 130 to be formed on the surfaces of the first conductive patterns 112a and the conductive pillars 122 to a predetermined thickness. The embodiment is described with regard to the copper plate by way of example, but aspects of the present invention are not limited thereto.

In an example scenario, the second conductive patterns 112b formed on the second surface 111b of the unit substrate 110 may be prevented from being exposed to the outside using an insulating layer or a protection layer, thereby preventing the plating layer 130 from being formed on the surfaces of the second conductive patterns 112b.

As illustrated in FIG. 2C, in the encapsulating step, the semiconductor die 120 on the unit substrate 110 may be encapsulated using the encapsulant 150. Before the encapsulating, the underfill 140 may be injected into a gap between the unit substrate 110 and the semiconductor die 120. Accordingly, the plating layer 130 may be completely surrounded by the underfill 140.

As illustrated in FIG. 2D, in the solder ball bonding step, solder balls 160 may be bonded to the second conductive patterns 112b exposed through the second surface 111b of the unit substrate 110. As an example, volatile flux may be dotted to the second conductive patterns 112b, the solder balls 160 may be temporarily attached to the flux, followed by a reflow process at a temperature of approximately 150 to 250° C., thereby removing the volatile flux and welding (or wetting) the solder balls 160 to the second conductive patterns 112b. Thereafter, a cooling process may be performed to allow the solder balls 160 to be attached to the second conductive patterns 112b in a hardened state.

As illustrated in FIG. 2E, in the sawing step, the unit substrate 110 may be separated from the panel substrate 110p using a blade 170, thereby providing the individual semiconductor device 100. Here, the blade 170 may saw the encapsulant 150 and the unit substrate 110. In addition, the blade 170 may saw the bus bars 110b formed at a boundary region of the unit substrate 110, thereby electrically isolating all of the first conductive patterns 112a or the second conductive patterns 112b provided in the unit substrate 110.

FIG. 3A is a bottom view illustrating a panel substrate in the manufacturing method of a semiconductor device according to an example embodiment of the present disclosure, and FIG. 3B is a bottom view illustrating a unit substrate including bus bars.

As illustrated in FIG. 3A, a panel substrate 110p comprises a plurality of unit substrates 110. For example, the panel substrate 110p may comprise 3×3 unit substrates 110. In addition, the panel substrate 110p may include a plurality of the 3×3 unit substrates 110.

As described above, according to an example embodiment of the present disclosure, the semiconductor die 120 and the substrate 110 (for example, a circuit board) may be electrically connected using a plating process not necessitating a thermal process, thereby suppressing warpage due to the thermal processes and manufacturing the semiconductor device 100 based on a large-sized panel method.

As illustrated in FIG. 3B, a plurality of second conductive patterns 112b may be provided on a bottom surface of the unit substrate 110, and the plurality of second conductive patterns 112b are connected to bus bars 110b provided at a boundary region between the unit substrates 110.

Therefore, if a negative potential, for example, is applied to the bus bars 110b, the negative potential may also be applied to all of the second conductive patterns 112b and the first conductive patterns 112a connected to the bus bars 110b, thereby facilitating a plating process.

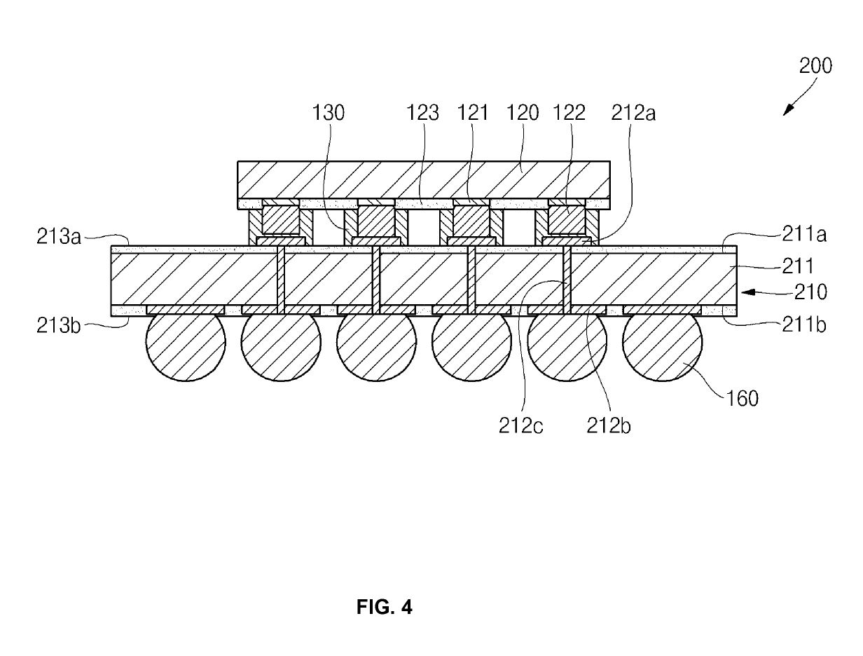

FIG. 4 is a cross-sectional view of a semiconductor device according to another example embodiment of the present disclosure.

As illustrated in FIG. 4, the semiconductor device 200 according to another example embodiment of the present disclosure may comprise a substrate 210 that is a second semiconductor die or wafer. The second semiconductor die 210 may comprise silicon 211 having a planar first surface 211a and a planar second surface 211b opposite to the first surface 211a. The silicon 211 may comprise, for example, an integrated circuit. In addition, first conductive patterns 212a may be formed on the first surface 211a and second conductive patterns 212b may be formed on the second surface 211b. Here, the first conductive patterns 212a may be general conductive pads, and the second conductive patterns 212b may be general bond pads or redistribution layers.

In addition, the first conductive patterns 212a and the second conductive patterns 212b may be connected to each other through a through silicon via 212c passing through the silicon 211.

Additionally, a first protection layer 213a may be formed between the first conductive patterns 212a and the first surface 211a of the silicon 211, thereby preventing the first conductive patterns 212a from making direct contact with the first surface 211a of the silicon 211. In addition, the second surface 211b of the silicon 211 and the second conductive patterns 212b may be protected by a second protection layer 213b.

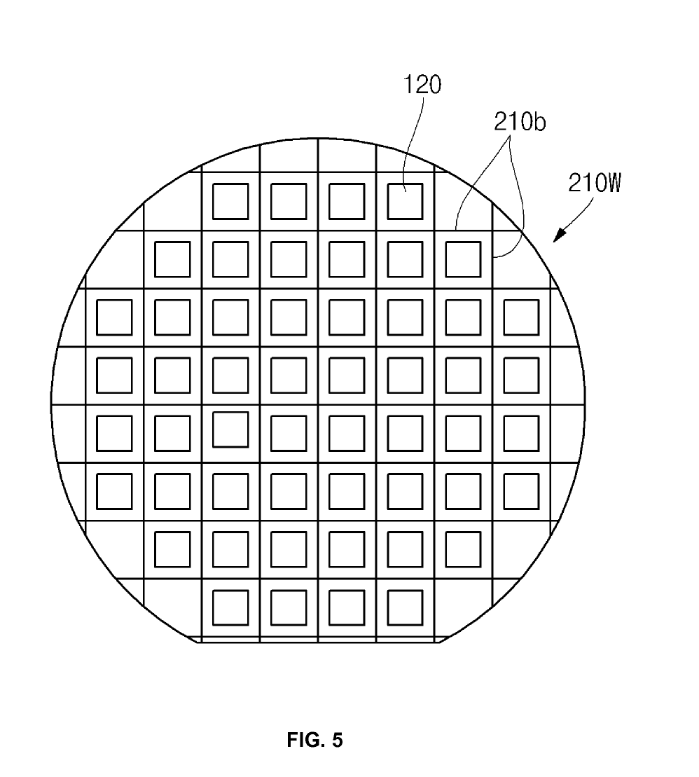

FIG. 5 is a plan view illustrating a state in which a plurality of semiconductor dies are mounted on a wafer in a manufacturing method of a semiconductor device according to an example embodiment of the present disclosure.

As illustrated in FIG. 5, in the manufacturing method of a semiconductor device according to an example embodiment of the present disclosure, a plurality of semiconductor die 120 may be mounted on a wafer 210w (or a second semiconductor die). Here, bus bars 210b electrically connected to first conductive patterns or second conductive patterns may also be provided on the wafer 210w. In addition, the bus bars 210b may be formed on a saw street line of the wafer 210w so as to be removed in a sawing process of the wafer 210w.

This disclosure provides exemplary embodiments supporting the present invention. The scope of the present invention is not limited by these exemplary embodiments. Numerous variations, whether explicitly provided for by the specification or implied by the specification, such as variations in structure, dimension, type of material and manufacturing process, may be implemented by one skilled in the art in view of this disclosure.

In an example embodiment of the disclosure a semiconductor device with plated conductive pillar coupling is disclosed and may comprise a semiconductor die comprising a conductive pillar formed on a bond pad on the semiconductor die, a substrate comprising an insulating layer with conductive patterns formed on a first surface and a second surface opposite to the first surface of the substrate, and a plating layer electrically coupling the conductive pillar and the bond pad on the first surface of the semiconductor die to the conductive pattern on the first surface of the substrate. The conductive pillar, the conductive patterns, and the plating layer may comprise copper, for example. The plating layer may fill a void between the copper pillar and the conductive pattern on the first surface of the substrate. The substrate may comprise a rigid circuit board, a flexible circuit board, a ceramic substrate, a semiconductor die, or semiconductor wafer. The plating layer may form a cylindrical shape around the conductive pillar and the conductive pattern on the first surface of the substrate. The substrate may comprise conductive vias that electrically couple the conductive patterns on the first and second surfaces of the substrate. A solder ball may be formed on the conductive patterns on the second surface of the substrate. An encapsulating material may encapsulate the semiconductor die and the first surface of the substrate. An underfill material may be formed between the first surface of the semiconductor die and the first surface of the substrate. The underfill material may surround the plating layer.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A semiconductor device comprising:
a semiconductor die comprising a conductive pillar formed on a bond pad on the semiconductor die;
a substrate comprising an insulating layer having a conductive pattern formed on a first surface of the substrate; and
a plating layer electrically coupling the conductive pillar and the bond pad on the semiconductor die to the conductive pattern on the first surface of the substrate.

2. The semiconductor device according to claim 1, wherein the conductive pillar, the conductive pattern, and the plating layer comprise copper.

3. The semiconductor device according to claim 1, wherein the conductive pillar, the conductive pattern, and the plating layer consist of a same material.

4. The semiconductor device according to claim 1, wherein the plating layer fills a void between the copper pillar and the conductive pattern on the first surface of the substrate.

5. The semiconductor device according to claim 1, wherein the substrate comprises a rigid circuit board, a flexible circuit board, a ceramic substrate, a semiconductor die, or semiconductor wafer.

6. The semiconductor device according to claim 1, wherein the plating layer forms a cylindrical shape around the conductive pillar and the conductive pattern on the first surface of the substrate.

7. The semiconductor device according to claim 1, wherein the substrate comprises conductive vias that electrically couple the conductive pattern on the first surface of the substrate with a second conductive pattern on a second surface of the substrate.

8. The semiconductor device according to claim 1, wherein a solder ball is formed on a second conductive pattern on a second surface of the substrate.

9. The semiconductor device according to claim 1, wherein an encapsulating material encapsulates the semiconductor die and the first surface of the substrate.

10. The semiconductor device according to claim 1, wherein an underfill material is formed between the first surface of the semiconductor die and the first surface of the substrate.

11. A method for a semiconductor device, the method comprising:
forming a conductive pillar on a bond pad on a semiconductor die;
forming a conductive pattern on a first surface of a substrate that comprises an insulating layer; and
forming a plating layer that electrically couples the conductive pillar and the bond pad on the semiconductor die to the conductive pattern on the first surface of the substrate.

12. The method according to claim 11, wherein the conductive pillar, the conductive pattern, and the plating layer comprise copper.

13. The method according to claim 11, wherein the conductive pillar, the conductive pattern, and the plating layer consist of a same material.

14. The method according to claim 11, comprising filling a void between the copper pillar and the conductive pattern on the first surface of the substrate utilizing the plating layer.

15. The method according to claim 11, wherein the substrate comprises a rigid circuit board, a flexible circuit board, a ceramic substrate, a semiconductor die, or semiconductor wafer.

16. The method according to claim 11, wherein the plating layer forms a cylindrical shape around the conductive pillar and the conductive pattern on the first surface of the substrate.

17. The method according to claim 11, wherein the substrate comprises conductive vias that electrically couple the conductive pattern on the first surface of the substrate with a second conductive pattern on a second surface of the substrate.

18. The method according to claim 11, comprising forming a solder ball on a second conductive pattern on a second surface of the substrate.

19. The method according to claim 11, comprising forming an underfill material between the semiconductor die and the first surface of the substrate.

20. A semiconductor device, the device comprising:
a semiconductor die comprising a conductive pillar formed on a bond pad on the semiconductor die;
a panel substrate comprising an insulating layer having conductive patterns formed on a first surface of the panel substrate and on a second surface opposite to the first surface; and
a plating layer electrically coupling the conductive pillar and the bond pad on the semiconductor die to the conductive pattern on the first surface of the panel substrate.
